(19) United States
(12) Patent Application Publication
(10) Pub. No.: US 2026/0170207 A1
(43) Pub. Date: Jun. 18, 2026

(54) DIE DESIGN SYSTEM

(71) Applicant: G-TEKT CORPORATION, Saitama-shi, Saitama (JP)

(72) Inventors: Tomio Saitou, Koka-shi, Shiga (JP); Akira Kakizaki, Hamura-shi, Tokyo (JP); Hiroki Itoi, Hamura-shi, Tokyo (JP); Rie Aoki, Hamura-shi, Tokyo (JP)

(21) Appl. No.: 18/853,915

(22) PCT Filed: May 30, 2024
(86) PCT No.: PCT/JP2024/019810

§ 371 Date: Oct. 3, 2024

(30) Foreign Application Priority Data
May 30, 2023 (JP) 2023-088352
Jan. 12, 2024 (JP) 2024-002914

(51) Int. Cl. G06F 30/31; G06F 30/32

(52) U.S. Cl. CPC G06F 30/31; G06F 30/32

(57) ABSTRACT

A die design system includes a computer, stores die data having a plurality of shape data in a storage unit, and prompts a user to set first shape data via a display device, an input device, The first shape data is enlarged or reduced at a desired magnification with respect to a predetermined reference point, such that the user enlarges or reduces the die data at the desired magnification. The die design system prompts the user to set second shape data among the plurality of shape data. The second shape data is moved at a magnification of 100% with respect to the predetermined reference point or the first shape data. The die design system prompts the user to set shape data of attachment portions among the second shape data, which adjusts a position after being moved.

### TECHNICAL FIELD

The present invention relates to a die design system using computer-aided design (CAD).

### BACKGROUND ART

As die design systems using CAD, various types of systems have been put into practical use (for example, refer to Patent Document 1 (FIG. 5 and FIG. 10)).

Patent Document 1 will be described based on the following drawings.

FIG. 8A and FIG. 8B are views describing a conventional die design system.

As shown in FIG. 8A, a die 101 comprises a product shape forming portion 102 having a form conforming to a shape of a product, and a die structure portion 103 that supports the product shape forming portion 102.

Attachment portions such as a guide post 104 that engages an upper die with a lower die, a cam 105 that plays a role in bending a workpiece (thin steel sheet to be subjected to processes such as forming, and the same applies below), a scrap cutter 106 that cuts off unnecessary portions of the workpiece, and a spring 107 that equalizes a force applied to the workpiece are attached to the die structure portion 103.

Furthermore, a central portion of the product shape forming portion 102 is defined as a center O1 (Patent Document 1, paragraph 0044), and feature points indicated by P1 to P6 to P11 are assigned clockwise to the product shape forming portion 102.

The coordinates of the product shape forming portion 102, the die structure portion 103, and the attachment portions are moved two-dimensionally (or three-dimensionally) with respect to the feature points P1 to P11.

As a result, for example, a new die 201 shown in FIG. 8B is obtained. The new die 201 is composed of a new product shape forming portion 202 and a new die structure portion 203.

Attachment portions such as a new guide post 204, a new cam 205, a new scrap cutter 206, and a new spring 207 are attached to the die structure portion 203.

Namely, Patent Document 1 discloses a die design system that is characterized by assigning a plurality of feature points to a product shape forming portion, and automatically creating new die structure portion data with respect to the feature points. The die design system has the advantage that all product shape forming portions can be created by CAD.

On the other hand, the technique of Patent Document 1 has the following disadvantages.

As is clear from FIG. 8A and FIG. 8B, according to the technique of Patent Document 1, the new cam 205 is reduced at the same ratio as an expansion/contraction ratio of the new product shape forming portion 202.

Similarly, the attachment portions such as the new scrap cutter 206 and the new spring 207 are also reduced at the same ratio as the expansion/contraction ratio of the new product shape forming portion 202.

Taking the cam as an example, each dimension of the new cam 205 changes in increments of 1 mm or increments of 0.1 mm with respect to the cam 105.

In order to manufacture the new cam 205, it is necessary to prepare a new drawing in which each dimension is corrected in increments of 1 mm or increments of 0.1 mm.

Namely, in addition to the drawing of the cam 105, it is necessary to prepare a drawing for the new cam 205, so that the cost of creating the drawings is increased. The same applies to the attachment portions such as the new scrap cutter 206 and the new spring 207.

Namely, in the technique of Patent Document 1, die design costs are increased.

In the context of a desire to reduce die manufacturing costs, a die design system capable of reducing die design costs is desired.

### CONVENTIONAL ART LIST

### Patent Document

Patent Document 1: Japanese Application No. H8-287115

### SUMMARY OF THE INVENTION

### Problem to be Solved by the Invention

An object of the invention is to provide a die design system capable of reducing die design costs.

### Means for Solving Problem

In order to solve the above-described problem, according to a first aspect, there is provided a die design system for designing a new die having a magnification different from a magnification of a reference die when the magnification of the reference die is set to 100%. Reference die data having a plurality of shape data is stored, and a user is prompted to set new die data to have first shape data among the plurality of shape data, the first shape data being enlarged or reduced at a desired magnification of more than 100% or less than 100% with respect to a predetermined reference point, such that the user enlarges or reduces the die data at the desired magnification. The user is prompted to set the new die data to have second shape data among the plurality of shape data, the second shape data being moved at a magnification of 100% with respect to the predetermined reference point or the first shape data. A position of the predetermined reference point is restricted from being moved.

Preferably, according to a second aspect, in the first aspect, the first shape data includes shape data of at least one of a workpiece receiving portion, an insert, and a die structure portion constituting the reference die, and the second shape data includes shape data of an attachment portion constituting the reference die, and the attachment portion includes at least one of a cam, scrap cutter, a spring, a U-groove, a lifting bar, a locator, and a piercing punch.

Preferably, according to a third aspect, in the first aspect, the second shape data is a plurality of second shape data, and the user is prompted to set at least one of the plurality of second shape data as position adjustment shape data to adjust a position after being moved with respect to the predetermined reference point.

Preferably, according to a fourth aspect, in any one of the first to third aspects, the reference die data is die data for manufacturing a transfer press die, and the predetermined reference point corresponds to a center of the transfer press die.

Preferably, according to a fifth aspect, in any one of the first to third aspects, the desired magnification is set in a range of more than 100% and less than 120 during the enlargement, and/or is set in a range of 80% or more and less than 100% during the reduction.

Preferably, according to a sixth aspect, in the third aspect, the position adjustment shape data is set to release a restriction on a movement from the position moved by a movement amount with respect to the predetermined reference point based on the desired magnification, then to move the second shape data to an adjusted position, and then to move the position with respect to the predetermined reference point.

Preferably, according to a seventh aspect, in any one of the first to third aspects, the first shape data and the second shape data are displayed, and the second shape data is moved by enlarging or reducing the first shape data at the desired magnification.

Preferably, according to an eighth aspect, in the seventh aspect, in response to an operation of a mouse, an external dimension frame of the reference die data is enlarged or reduced in real time, and the external dimension frame, the first shape data, and the second shape data are displayed.

Preferably, according to a ninth aspect, in any one of the first to third aspects, the reference die and a neighboring die of the reference die are used together in a transfer press, and a maximum dimension of the reference die, which is a maximum value of the desired magnification, is restricted by a disposition position of the neighboring die.

### Advantage of the Invention

In the first aspect, among the plurality of shape data constituting the reference die data, the first shape data is enlarged or reduced by a magnification α.

On the other hand, among the plurality of shape data, the second shape data is neither enlarged nor reduced regardless of the magnification α. Namely, among the plurality of shape data, the second shape data only needs to be moved in position, and does not require design to correct each dimension in increments of 1 mm or increments of 0.1 mm, which is necessary when the second shape data is enlarged or reduced.

As a result, the new die having a magnification different from the magnification of the reference die is easily set by a simple operation, and die design costs are reduced.

Incidentally, the reference die data may include, for example, three-dimensional design data (CAD data) as one example, and the reference die data may include, for example, reference model data as one example which enables the shape of the reference die to be displayed three-dimensionally on a display device.

In the second aspect, the attachment portions such as the cam, the scrap cutter, the spring, the U-groove, the lifting bar, the locator, and the piercing punch are neither enlarged nor reduced regardless of the magnification α, but move at a magnification of 100% with respect to the predetermined reference point as the workpiece receiving portion, the insert, the die structure portion, and the like constituting the reference die are enlarged or reduced.

Namely, the need for tedious data input or correction in moving the attachment portions can be reduced.

In addition, since the attachment portions such as the cams, the scrap cutters, the springs, the U-grooves, the lifting bars, the locators, and the piercing punches have the same shape, there is no need to manufacture new attachment components. When the attachment components are standard components, the attachment components can be purchased at low cost.

In the third aspect, when the second shape data (typically, the attachment portions) is moved, in a case where simply moving the second shape data with respect to the predetermined reference point as the workpiece receiving portion, the insert, the die structure portion, and the like are enlarged or reduced is not sufficient, for example, the position of the second shape data (position adjustment shape data) of the U-groove, the lifting bar, and the like after the movement can be adjusted.

In the fourth aspect, costs when die data for manufacturing the transfer press die is designed can be reduced.

In the fifth aspect, by setting the upper limit of the magnification α when the first shape data is enlarged to 120%, and setting the lower limit of the magnification α when the first shape data is reduced to 80%, a decrease in the strength of the new die for the second shape data that is neither enlarged nor reduced regardless of the magnification α can be prevented.

In the sixth aspect, the position adjustment shape data (second shape data that moves with respect to the predetermined reference point) releases the constraint with respect to the predetermined reference point, adjusts the position thereof, and resets the constraint with respect to the predetermined reference point after the adjustment is ended. Accordingly, when the magnification α that is set once is changed, the second shape data can be moved with reference to the predetermined reference point according to the change in the magnification α.

In the seventh aspect, the user can set the magnification α while visually confirming the expansion/contraction of the first shape data and the movement of the second shape data.

In the eighth aspect, the user can set the magnification α while easily visually confirming the operation of the enlargement or reduction of the external dimensions of the reference die data in real time in response to the operation of the mouse.

In the ninth aspect, the maximum dimension that is the upper limit of the magnification α during the enlargement can be restricted in relation to the neighboring die.

### BRIEF DESCRIPTION OF DRAWINGS

FIG. 1 is a perspective view of a trimming lower die;

FIG. 2 is a view describing a transfer press die;

FIG. 3A is a view describing a model die, and FIG. 3B is a view describing a new die;

FIG. 4A is a diagram describing a CAD system, and FIG. 4B is a diagram describing a computer constituting the CAD system;

FIG. 5 is a view describing a free expansion/contraction function;

FIG. 6 is a view describing a component movement function;

FIG. 7A, FIG. 7B, and FIG. 7C are view describing a movement adjustment function; and

FIG. 8A and FIG. 8B are views describing a conventional die design system.

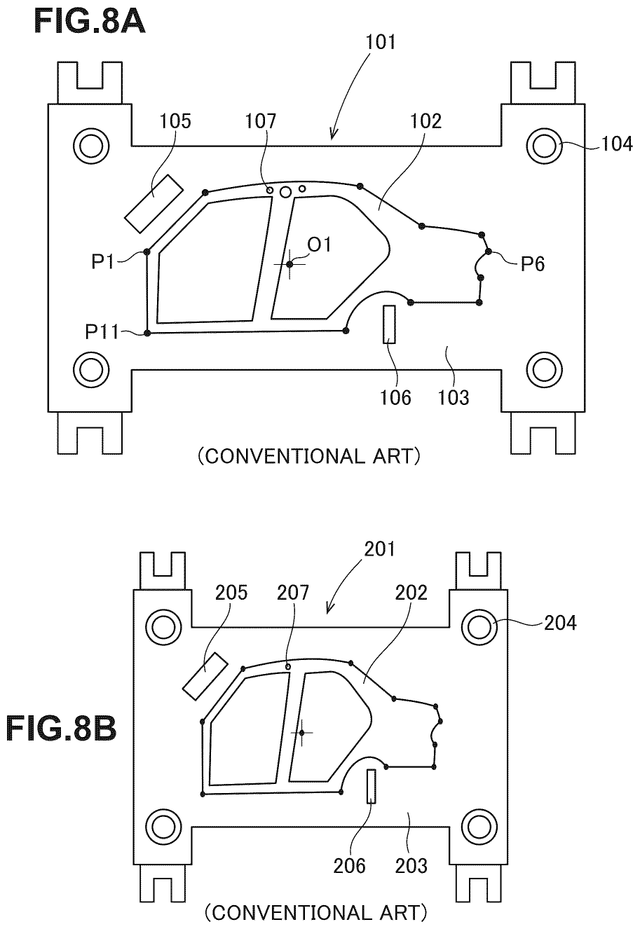

### EMBODIMENT(S) FOR CARRYING OUT THE INVENTION

An embodiment of the invention will be described below based on the accompanying drawings.

### EXAMPLES

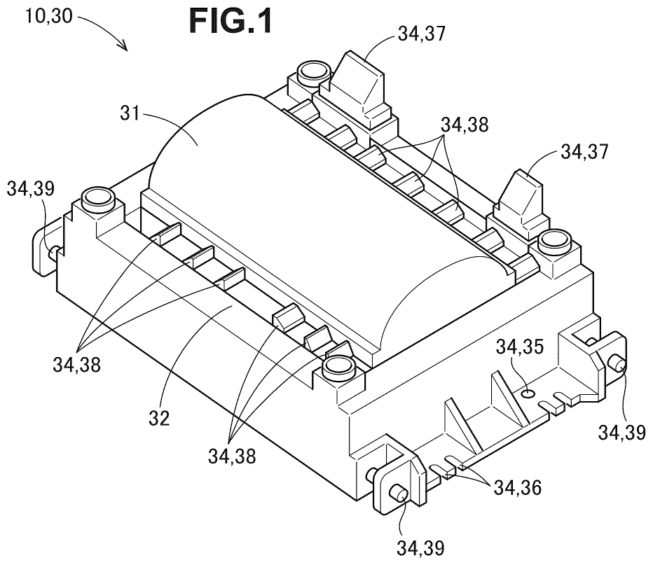

As shown in FIG. 1, a die 10 is, for example, a trimming lower die 30.

The trimming lower die 30 comprises a workpiece receiving portion 31 that receives (or supports) a workpiece, and a die structure portion 32 that has a substantially rectangular shape that is horizontally long, and the die structure portion 32 supports the workpiece receiving portion 31.

For example, attachment portions 34 as will be described below are attached to the die structure portion 32.

The attachment portions 34 are a locator 35 and a U-groove 36 that are used for positioning in a horizontal direction; a cam 37 that converts an up and down movement into a horizontal movement; a scrap cutter 38 that cuts off unnecessary portions of the workpiece; lifting bars 39 disposed at four corners; and others.

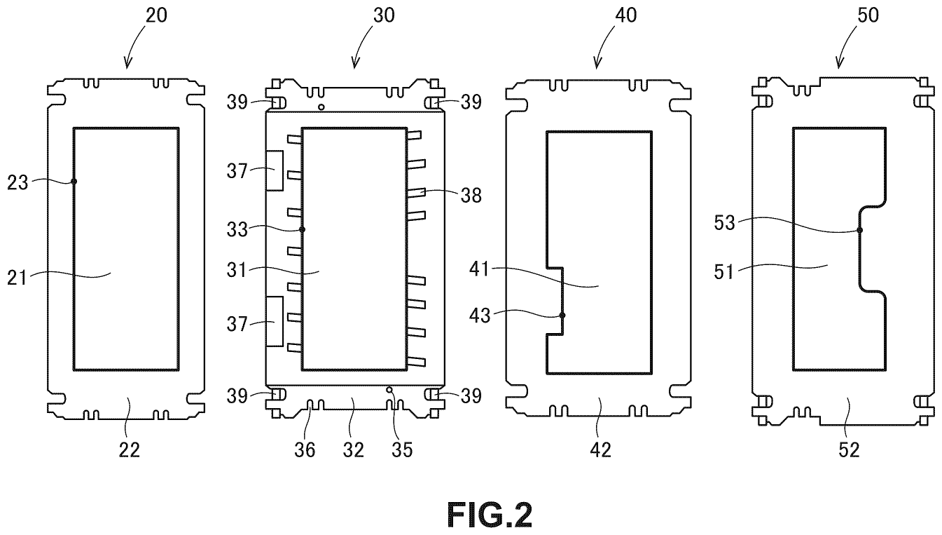

As shown in FIG. 2, in the transfer press, a drawing lower die 20, the trimming lower die 30, a piercing lower die 40, and a bending lower die 50 are disposed in order along a traveling direction of the workpiece. Incidentally, in FIG. 2, neighboring dies are depicted separately for ease of viewing, but in reality, are densely disposed in close proximity. By densely disposing the dies 20, 30, 40, and 50, all the dies 20, 30, 40, and 50 can be stored in one press machine.

The drawing lower die 20 is used in a drawing process to draw the workpiece, which is referred to as a blank material, into a product shape. A flat sheet is formed into a three-dimensionally drawn form by the drawing process.

The drawing lower die 20 is a die including, as main portions, a product shape forming portion 21 having a form conforming to the shape of a product, and a die structure portion 22 that supports the product shape forming portion 21.

The die structure portion 22 is provided with an attachment portion. Furthermore, the die structure portion 22 has a rectangular shape having larger vertical and horizontal dimensions than the product shape forming portion 21.

Hereinafter, an outer contour line (outer diameter contour line) of the product shape forming portion 21 will be referred to as a profile 23. The profile 23 closely resembles an outer contour line of the product.

When the drawing process is completed, the workpiece is transferred to the neighboring trimming lower die 30 by transfer equipment associated with a transfer press machine. At the same time, the workpiece having a flat sheet shape is put into the empty drawing lower die 20.

The trimming lower die 30 is used in an edge cutting process to cut off the edges of the drawn workpiece.

The trimming lower die 30 is a die including, as main portions, the workpiece receiving portion 31 and the die structure portion 32 that supports the workpiece receiving portion 31.

The die structure portion 32 is provided with the attachment portions (the locator 35, the U-groove 36, the cam 37, the scrap cutter 38, and the lifting bars 39). The die structure portion 32 has a rectangular shape having larger vertical and horizontal dimensions than the workpiece receiving portion 31.

A profile 33 that is the outer contour line of the workpiece receiving portion 31 closely resembles the outer contour line of the product.

The edges (edge material) separated from the workpiece by the trimming process are cut to a predetermined length by the scrap cutter 38, and are discharged to the outside of the machine.

When the trimming process is completed, the workpiece is transferred to the neighboring piercing lower die 40 by the transfer equipment. At the same time, the drawn workpiece is put into the empty trimming lower die 30.

The piercing lower die 40 is composed of a workpiece receiving portion 41 that receives the workpiece with the edges cut off, and a die structure portion 42 that supports the workpiece receiving portion 41.

The die structure portion 42 is provided with attachment portions. The die structure portion 42 has a rectangular shape having larger vertical and horizontal dimensions than the workpiece receiving portion 41.

The piercing lower die 40 is used in a hole-making process to make holes at predetermined locations of the workpiece using a piercing punch.

Since a profile 43 of the workpiece receiving portion 41 is determined the number and positions of the piercing punches, the profile 43 in the piercing lower die 40 is considerably different from the profile 23 in the drawing lower die 20.

When the hole-making process is completed, the workpiece is transferred to the neighboring bending lower die 50 by the transfer equipment. At the same time, the workpiece with the edges cut off is put into the empty piercing lower die 40.

The bending lower die 50 is composed of a workpiece receiving portion 51 that receives the workpiece subjected to the piercing process, and a die structure portion 52 that supports the workpiece receiving portion 51.

The die structure portion 52 is provided with attachment portions. The die structure portion 52 has a rectangular shape having larger vertical and horizontal dimensions than the workpiece receiving portion 51.

The bending lower die 50 is used in a bending process to bend predetermined locations (mainly edges) of the workpiece to form the final product shape.

Since a profile 53 of the workpiece receiving portion 51 is determined by the positions where bending is performed and the degree of bending, the profile 53 in the bending lower die 50 is significantly different from the profile 23 in the drawing lower die 20.

In the above description, various terms have been listed.

Table 1 shows a comparison of these terms with the terms used in Patent Document 1 listed as the conventional art.

TABLE 1

| Conventional art (Patent Document 1) | The Invention |
|---|---|
| Die | Die |
| \|- Product shape forming portion | \|- Product shape forming portion |
| \| | or workpiece receiving portion |
| \|- Die structure portion | \| \| |
| \| | \| \|(including) |
| \|(including) | \| \| |
| \| | \| \|- Insert |
| \|- Attachment portion | \| \|- Cutting blade |
| \|- Cam | \| \|- Curved blade |
| \|- Scrap cutter | \| |
| \|- Spring | \|- Die structure portion |
| | \| |
| | \| (including) |
| | \| |
| | \|- Attachment portion |
| | \|- Cam |
| | \|- Scrap cutter |
| | \|- Spring |
| | \|- U-groove |
| | \|- Lifting bar |
| | \|- Locator |
| | \|- Piercing punch |
| | \|- Others |

The product shape forming portion and the workpiece receiving portion of the invention correspond to the product shape forming portion in the conventional art.

Incidentally, the product shape forming portion or the workpiece receiving portion includes an insert such as a cutting blade or a curved blade (also referred to as an insert fitting or an insert steel).

The attachment portions in the conventional art are a cam, a scrap cutter, and a spring, whereas the attachment portions of the invention are a U-groove, the lifting bars, a locator, a piercing punch, and others in addition to a cam, a scrap cutter, and a spring.

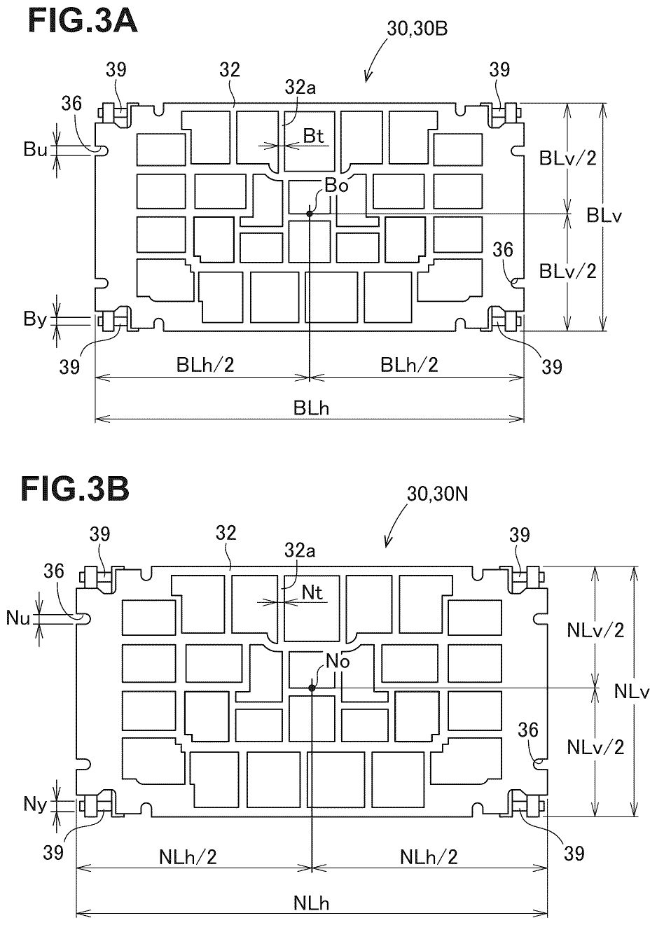

FIG. 3A is a bottom view of the trimming lower die 30 shown in FIG. 1. The die structure portion 32 having a rectangular shape that is horizontally long is partitioned into portions by a plurality of ribs 32a. Since the partitioned portions become lightening portions, a reduction in the weight of the die structure portion 32 is measured. The lifting bars 39 are visible at the four corners, and the U-grooves 36 are visible on a left side and a right side.

The trimming lower die 30 shown in FIG. 3A is read as a base die 30B.

A horizontal dimension of the base die 30B is BLh, a vertical dimension of the base die 30B is BLv, a thickness of the rib 32a is Bt, the center of the base die 30B is Bo, a diameter of the lifting bar 39 is By, and a groove width of the U-groove 36 is Bu.

Here, the center Bo is determined at a position located at 1/2 of BLh and 1/2 of BLv.

Conventionally, the center of the product shape forming portion is set as the center; however, in the invention, the center of the die structure portion 32 is determined as the center. When the center of the die structure portion 32 is determined as the center, expansion/contraction or movement on an XY plane can be performed symmetrically with respect to the center of the die structure portion 32. As a result, the die structure is well balanced, and the attachment portions attached to the die are easier to manage.

The die design system according to the invention makes it possible to design a new die that is expanded or contracted at a predetermined expansion/contraction ratio using the base die 30B described above as a base.

The expansion/contraction ratio is read as a magnification α. When the magnification α is more than 100%, the die design is enlarged, and when the magnification α is less than 100%, the die design is reduced.

The die design system according to the invention will be described later, and according to the die design system, a new die 30N shown in FIG. 3B is designed.

In FIG. 3B, a horizontal dimension of the new die 30N is NLh, a vertical dimension of the new die 30N is NLv, a thickness of the rib 32a is Nt, the center of the new die 30N is No, a diameter of the lifting bar 39 is Ny, and a groove width of the U-groove 36 is Nu.

In the invention, NLh is determined by the formula: BLh×α. Similarly, NLv is determined by the formula: BLv×α. Nt is determined by the formula: Bt×α. Similarly, the product shape forming portion (FIG. 2, reference numeral 31) is multiplied by α. The die design system according to the invention is a die design system that multiplies the product shape forming portion by α to create new die data.

On the other hand, the center No is determined at a position located at 1/2 of NLh and 1/2 of NLv. Namely, there is no change in that the position of the center is determined at the center of the new die 30N.

In addition, the diameter Ny of the lifting bar 39 is the same as By, and the groove width Nu of the U-groove 36 is the same as Bu.

When the magnification α is less than 80%, first shape data is reduced, but second shape data is not reduced, so that there is a risk of interference. In addition, the rib thickness becomes too thin, so that there is a risk of deformation, and there occurs a need to reconsider the strength of the die. In addition, when the magnification α is more than 120%, the positional balance between the enlarged first shape data and the non-enlarged second shape data becomes poor, so that it is necessary to correct the second shape data. In addition, the rib pitch also becomes too wide, so that there is a risk of bending, and there occurs a need to reconsider the strength of the die. For that reason, the magnification α is preferably set to 80% or more and 120% or less.

When the pressing force of the press machine is high, the magnification α is still more preferably set to 90% or more and 110% or less in consideration of the necessity to maintain a certain degree of rib thickness of the die and the rib pitch. The reason is that the enlarged or reduced data is used as the die data as it is without being corrected.

Namely, in the die design system of the invention, in Table 1 described above, the product shape forming portion (or the workpiece receiving portion) and the die structure portion are enlarged or reduced by the magnification α.

On the other hand, in Table 1, the attachment portions are neither enlarged nor reduced regardless of the magnification α.

As a result, the new die 30N shown in FIG. 3B is easily set.

Hereinafter, the die design system of the invention will be described in detail.

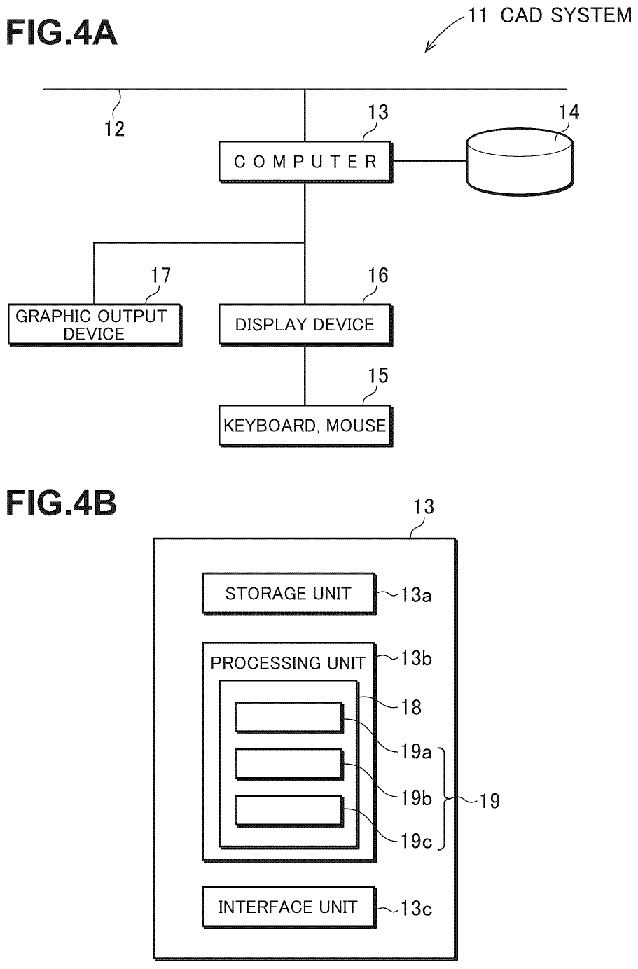

FIG. 4A is a descriptive diagram of a configuration example of a CAD system 11 (die design system) for designing, for example, the die 10 such as the trimming lower die 30 shown in FIG. 1, and the same configuration as a known CAD system can be adopted as the configuration of the CAD system 11.

The CAD system 11 includes, for example, a computer 13 connected to a network 12 such as Ethernet (registered trademark); a display device 16 connected to the computer 13; and an input device 15 such as a keyboard and a mouse.

As shown in FIG. 4A, the computer 13 can include, for example, an external storage device 14 or a database (die database) for storing die data constituting a plurality of completed dies for the transfer press, and calling up desired die data from a plurality of die data.

In addition, the computer 13 can include, for example, a graphic output device 17 capable of outputting drawings required for manufacturing the die 10 from the die data.

Incidentally, a known computer-aided manufacturing (CAM) system may be connected to the computer 13.

FIG. 4B is a descriptive diagram (functional block diagram) of a configuration example of the computer 13 constituting the CAD system 11 of FIG. 4A, and the computer 13 can include the same configuration as a known computer.

As shown in FIG. 4B, the computer 13 includes, for example, a storage unit 13a composed of a ROM, a RAM, an HDD, an SSD, and the like; a processing unit 13b composed of a CPU, an MPU, and the like; and an interface unit 13c for inputting and outputting various data, and connecting various peripheral devices, such as a USB port, a display port, and an Ethernet (registered trademark) port.

The ROM stores a program that causes the CPU or the MPU to execute a predetermined operation, and the RAM can form a work area for the CPU or the MPU. In addition, the HDD or the SSD can store data required for executing a CAD application installed or set in the computer 13 or the processing unit 13b.

The CAD application can include the same functions as a known CAD application, and for example, can prompt a user (operator) of the CAD system 11 or the computer 13 to design shape data representing the shapes of the workpiece receiving portion 31, the die structure portion 32, and the attachment portions 34 (the locator 35, the U-grooves 36, the cam 37, the scrap cutter 38, and the lifting bars 39) constituting the trimming lower die 30 shown in FIG. 1.

Namely, the processing unit 13b includes a die design function 18 (CAD function). Specifically, typically, the die design function 18 can, for example, generate a wireframe model from a plurality of shape data constituting the die data using feature points, line segments, curved lines, and the like, generates a solid model using three-dimensional shapes such as a rectangular parallelepiped, a cone, a column, a sphere, and a torus, generates a surface model based on wireframes, or generates a mesh model using three-dimensional shapes, surfaces, solids, and the like. These are one example, and the die design function 18 is provided with known CAD basic functions required for designing, saving, and reading the shape data included in the die 10.

As shown in FIG. 4B, the processing unit 13b or the die design function 18 can have, for example, additional functions 19 specific to the die design system of the invention, such as a free expansion/contraction function 19a, a component movement function 19b, and a movement adjustment function 19c. The additional functions 19 complement the known CAD basic functions or the die design function 18.

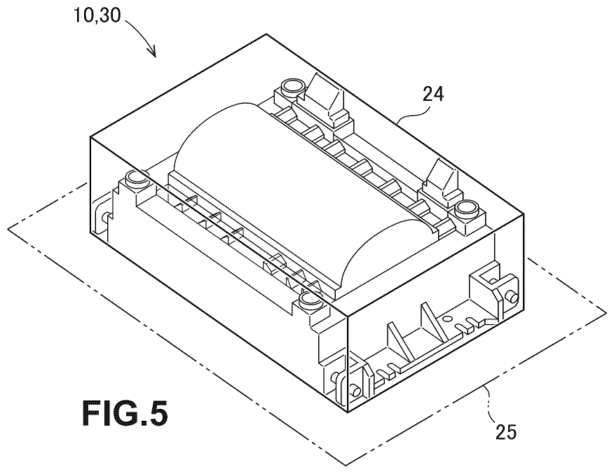

The computer 13 or the die design function 18 (CAD function) can, for example, read die data (reference die data) corresponding to the die 10 (reference die) such as the trimming lower die 30 in FIG. 1 from the external storage device 14, save or store the die data in the storage unit 13a, and display the die data on the display device 16 using the die data stored in the storage unit 13a (refer to FIG. 5).

As shown in FIG. 5, the computer 13 or the free expansion/contraction function 19a prompts the user to select (click), for example, the shape data of the trimming lower die 30 in FIG. 1 in a known manner, for example, using the mouse 15, and to display an external dimension frame 24, which represents the selection state, on the display device 16.

Thereafter, the user can enlarge or reduce the shape data of the trimming lower die 30 in a known manner by operating (dragging) or moving the mouse 15. At this time, the free expansion/contraction function 19a enlarges or reduces the external dimension frame 24 (preferably the shape data of the trimming lower die 30) in real time in response to the operation of the mouse 15, and displays the enlarged or reduced external dimension frame 24 on the display device 16.

Here, the external dimension frame 24 is, for example, a rectangular parallelepiped inscribed in the die data of the die 10 (trimming lower die 30), and an initial value of the external dimension frame 24 is a frame representing the volume of the reference die or the reference die data.

The user can end the enlargement or reduction of the shape data of the trimming lower die 30 in a known manner by operating (dropping) the mouse 15 while looking at the display device 16, and determine a desired magnification. At this time, the free expansion/contraction function 19a stores the determined desired magnification in the storage unit 13a.

Incidentally, the user may input the desired magnification, for example, via the keyboard 15 in a known manner.

As described above, as shown in FIG. 2, in the transfer press, the drawing lower die 20, the trimming lower die 30, the piercing lower die 40, and the bending lower die 50 are disposed in order along the traveling direction of the workpiece. Namely, since the trimming lower die 30 in FIG. 1 is arranged adjacent to the neighboring die, a maximum dimension is determined in advance, and is stored in, for example, the external storage device 14.

The free expansion/contraction function 19a can read maximum dimension data, which is associated with the die data, from the external storage device 14, save or store the maximum dimension data in the storage unit 13a, and display the maximum dimension data (maximum dimension 25 of the trimming lower die 30), which is stored in the storage unit 13a, on the display device 16, together with the die data (refer to FIG. 5). The user can easily understand a maximum magnification by recognizing the maximum dimension 25 that is displayed.

Preferably, the free expansion/contraction function 19a can calculate the maximum magnification from the maximum dimension data, and provide an upper limit for the desired magnification such that the magnification selected or input by the user does not become more than the maximum magnification. Namely, even when the user moves the mouse 15 more than necessary, the shape data of the external dimension frame 24 and the trimming lower die 30 can be calculated in real time until the external dimension frame 24 coincides with the maximum dimension 25.

Still more preferably, when the calculated maximum magnification is more than 120%, the free expansion/contraction function 19a can adopt 120%, which is smaller than the calculated maximum magnification, as the upper limit of the desired magnification α. Here, instead of 120%, 110% may be adopted as the upper limit of the desired magnification α that is smaller than the calculated maximum magnification. Similarly, preferably, the free expansion/contraction function 19a can adopt 80% as the lower limit of the desired magnification α. Here, instead of 80%, 90% may be adopted as the lower limit of the desired magnification α. In addition, when the calculated maximum magnification is more than the upper limit or the lower limit, the die design system may be set to be inoperable, a warning may be displayed, or an alarm may be issued.

By the way, the die data or the shape data can be represented by three-dimensional position coordinate data; however, in the transfer press, Z-axis position coordinate data (coordinate data in a direction perpendicular to the paper surface of FIG. 3) can be set to be constant. The die data or the shape data can be represented by two-dimensional position coordinate data (coordinate data in two directions perpendicular to each other in a plane parallel to the paper sheet of FIG. 3 (a vertical direction and the horizontal direction)) representing dimensions from the center Bo that is a reference point.

As described above, as shown in FIG. 3, in the invention, the horizontal dimension NLh of the new die 30N is determined by the formula: horizontal dimension BLh of the base die 30B×desired magnification α. Similarly, the vertical dimension NLv of the new die 30N is determined by the formula: vertical dimension BLv of the base die 30B×desired magnification α. The thickness Nt of the rib 32a is determined by the formula: thickness Bt of the rib 32a× desired magnification α. Similarly, the product shape forming portion (FIG. 2, reference numeral 31) is multiplied by the desired magnification α.

On the other hand, the center No (predetermined reference point) is determined at a position located at 1/2 of NLh (X-axis position coordinate data) and 1/2 of NLv (Y-axis position coordinate data). Namely, there is no change in that the position of the center (predetermined reference point) is determined at the center (predetermined reference point) of the new die 30N.

In addition, the diameter Ny of the lifting bar 39 is the same as By, and the groove width Nu of the U-groove 36 is the same as Bu.

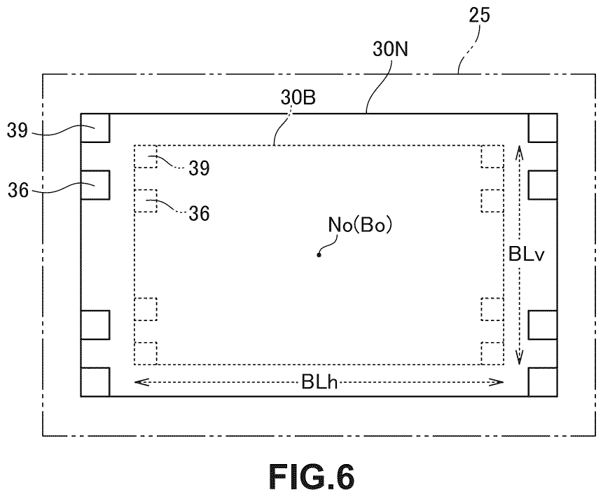

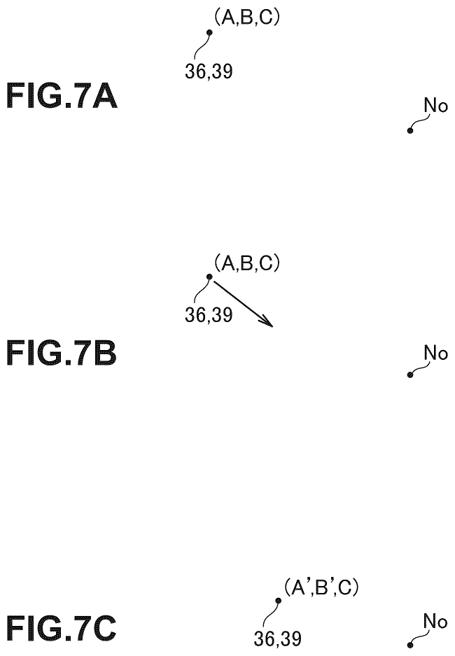

Therefore, the free expansion/contraction function 19a can enlarge (or reduce), for example, the die structure portion 32 (first shape data) among the plurality of shape data at the desired magnification α with respect to the predetermined reference points (centers Bo and No), and the component movement function 19b can move, for example, the lifting bars 39 and the U-grooves 36 (second shape data) among the plurality of shape data at a magnification of 100% (no enlargement and no reduction) with respect to the first shape data (a predetermined point or a predetermined shape) or the predetermined reference points (centers Bo and No) (refer to FIG. 6 and FIG. 7).

Here, the free expansion/contraction function 19a may prompt the user to set in advance whether the shape data belongs to the first shape data before the external dimension frame 24 representing the selection state of the plurality of shape data constituting the trimming lower die 30 is displayed, or prompt the user to additionally set whether the shape data belongs to the first shape data after the external dimension frame 24 is displayed.

Similarly, the component movement function 19b may prompt the user to set in advance whether the shape data belongs to the second shape data before the external dimension frame 24 is displayed by the free expansion/contraction function 19a, or prompt the user to additionally set whether the shape data belongs to the second shape data after the external dimension frame 24 is displayed.

Incidentally, in FIG. 6, the component movement function 19b may calculate a movement amount of the lifting bars 39 and the U-grooves 36 (second shape data) based on the movement amount of the first shape data such that, for example, the lifting bars 39 and the U-grooves 36 (second shape data) are aligned, for example, with respect to the feature points, a predetermined point such as a specific point, or a predetermined shape of the die structure portion 32 (first shape data).

Alternatively, in FIG. 6, the component movement function 19b may enlarge (or reduce), for example, the coordinates of representative points (X-axis position coordinate data and Y-axis position coordinate data) of the lifting bars 39 and the U-grooves 36 (second shape data) at the desired magnification α with respect to the predetermined reference points (center Bo and No), and restore, for example, the lifting bars 39 and the U-grooves 36 (second shape data) at a magnification of 100% (no enlargement and no reduction) with respect to the coordinates of the enlarged (or reduced) representative points (X-axis position coordinate data×α/2 and Y-axis position coordinate data×α/2).

Here, depending on the component, simply moving the die structure portion 32 or the like as the die structure portion 32 or the like is enlarged or reduced may not be sufficient. In this case, the positions of (representative points of) the second shape data after movement can be adjusted. Particularly, in the transfer press, since a plurality of dies are installed in the press machine, and there are also a large number of die components, the area where the components are disposed is likely to occupy the entire area inside the dies. For that reason, there may be interference with other components, equipment, or the like.

As shown in FIG. 7A, the computer 13 or the component movement function 19b can calculate, for example, a movement amount of the lifting bars 39 and the U-grooves 36 (second shape data) or the coordinates of the representative points (X-axis position coordinate data=A and Y-axis position coordinate data=B) of the second shape data (or any points of the second shape data), based on the desired magnification α with respect to the predetermined reference points (centers Bo and No), and move the second shape data.

The computer 13 or the movement adjustment function 19c can prompt the user to adjust the positions after movement if necessary. The movement adjustment function 19c can prompt the user to set or select position adjustment shape data from among a plurality of second shape data in order to release the constraint (position movement restriction) on, for example, the lifting bars 39 and the U-grooves 36 (second shape data) or, for example, the coordinates of the representative points (X-axis position coordinate data=A and Y-axis position coordinate data=B) of the second shape data with respect to the predetermined reference points (centers Bo and No). Incidentally, the predetermined reference points (centers Bo and No) are always constrained, and movement of the positions thereof is restricted. In addition, the predetermined reference point may be a point other than the centers Bo and No.

Thereafter, as shown in FIG. 7B and FIG. 7C, the movement adjustment function 19c can adjust the position adjustment shape data (second shape data) or, for example, the coordinates of the representative points (X-axis position coordinate data=A and Y-axis position coordinate data=B) in a known manner through the operation (dragging) of the mouse 15 by the user, or move the position adjustment shape data or the coordinates of the representative points of the position adjustment shape data to coordinates after the adjustment (X-axis position coordinate data=A′ and Y-axis position coordinate data=B′). At this time, the movement adjustment function 19c moves the entirety of the position adjustment shape data (second shape data) or, for example, the coordinates of the representative points of the position adjustment shape data in real time in response to the operation of the mouse 15, and displays the entirety of the position adjustment shape data or the coordinates of the representative points of the position adjustment shape data on the display device 16. Therefore, interference or balance state between components can be easily recognized.

After the position adjustment shape data or the positions or coordinates of the representative points thereof are adjusted, the movement adjustment function 19c can constrain the position adjustment shape data or the coordinates of the representative points thereof (X-axis position coordinate data=A′ and Y-axis position coordinate data=B′) (restrict the position movement of the lifting bars 39 and the U-grooves 36 (the position adjustment shape data among the second shape data)) in a known manner through the operation (click) of the mouse 15 by the user. When a constraint is imposed again, the points can function in the same manner even during the next free expansion and contraction.

Incidentally, the die design system of the invention is not limited to being applied to the trimming lower die 30 shown in FIG. 2, and can be applied to transfer press dies including the drawing lower die 20, the piercing lower die 40, and the bending lower die 50.

Further, the die design system of the invention can be widely applied to tandem press dies, progressive dies, and injection molds for obtaining resin molded articles, in addition to transfer press dies.

### EMBODIMENTS

Those skilled in the art can also grasp, for example, a plurality of the following embodiments.

According to a first embodiment, there is provided a die design system for designing a new die having a magnification different from a magnification of a reference die when the magnification of the reference die is 100%,
in which reference die data having a plurality of shape data is stored, and a user is prompted to set new die data to have among the plurality of shape data, the first shape data being enlarged or reduced at a desired magnification α more than 100% or less than 100% with respect to a center reference point of a die structure portion (32), such that the user enlarges or reduces the die data at the desired magnification α,
the user is prompted to set the new die data to have second shape data among the plurality of shape data, the second shape data being moved at a magnification of 100% where a shape of the second shape data is not changed with respect to the center reference point,
a position of the center reference point is restricted from being moved,
a movement amount of coordinates of a representative point of the second shape data with respect to the center reference point is calculated based on the desired magnification α, and
the first shape data and the second shape data are displayed, and the second shape data is moved by the movement amount by enlarging or reducing the first shape data at the desired magnification α.

According to a second embodiment, in the die design system according to the first embodiment,
an external dimension frame of the reference die data may be enlarged or reduced in real time in response to an operation of a mouse,
the movement amount of the coordinates of the representative point of the second shape data with respect to the center reference point in response to the operation of the mouse may be calculated in real time based on the desired magnification α, and
in response to the operation of the mouse, the external dimension frame, the first shape data, and the second shape data may be displayed in real time, and the second shape data may be moved by the movement amount in real time by enlarging or reducing the first shape data at the desired magnification α.

According to a third embodiment, in the die design system according to the first embodiment,
the desired magnification α may be set in a range of more than 100% and less than 120% during the enlargement, and/or may be set in a range of 80% or more and less than 100% during the reduction.

According to a fourth embodiment, there is provided a die design system for designing a new die having a magnification different from a magnification of a reference die when the magnification of the reference die is 100%,
in which reference die data having a plurality of shape data is stored, and a user is prompted to set new die data to have among the plurality of shape data, the first shape data being enlarged or reduced at a desired magnification α more than 100% or less than 100% with respect to a center reference point of a die structure portion (32), such that the user enlarges or reduces the die data at the desired magnification α,
the user is prompted to set the new die data to have second shape data among the plurality of shape data, the second shape data being moved at a magnification of 100% where a shape of the second shape data is not changed with respect to the center reference point,
a position of the center reference point is restricted from being moved, and
the desired magnification α is set in a range of more than 100% and less than 120% during the enlargement, and/or is set in a range of 80% or more and less than 100% during the reduction.

According to a fifth embodiment, in the die design system according to any one of the first to fourth embodiments,
the first shape data may include shape data of at least one of a workpiece receiving portion, an insert, and a die structure portion constituting the reference die, and
the second shape data may include shape data of an attachment portion constituting the reference die, and the attachment portion may include at least one of a cam, a scrap cutter, a spring, a U-groove, a lifting bar, a locator, and a piercing punch.

According to a sixth embodiment, in the die design system according to any one of the first to fourth embodiments,
the reference die data may be die data for manufacturing a transfer press die.

According to a seventh embodiment, in the die design system according to any one embodiment of claims 1 to 4,
the reference die and a neighboring die of the reference die may be used together in a transfer press, and a maximum dimension of the reference die, which is a maximum value of the desired magnification, may be restricted by a disposition position of the neighboring die.

### INDUSTRIAL APPLICABILITY

The invention is suitable for designing a transfer press die.

### EXPLANATIONS OF LETTERS OR NUMERALS

10 DIE
11 CAD SYSTEM
12 NETWORK
13 COMPUTER
13a STORAGE UNIT
13b PROCESSING UNIT
13c INTERFACE UNIT
14 STORAGE DEVICE (EXTERNAL STORAGE DEVICE, DIE DATABASE)
15 INPUT DEVICE (KEYBOARD, MOUSE)
16 DISPLAY DEVICE
17 GRAPHIC OUTPUT DEVICE
18 DIE DESIGN FUNCTION (CAD FUNCTION)
19 ADDITIONAL FUNCTION
19a FREE EXPANSION/CONTRACTION FUNCTION
19b COMPONENT MOVEMENT FUNCTION
19c MOVEMENT ADJUSTMENT FUNCTION
20 DRAWING LOWER DIE
21 PRODUCT SHAPE FORMING PORTION
22 DIE STRUCTURE PORTION
23 PROFILE
24 EXTERNAL DIMENSION FRAME
25 MAXIMUM DIMENSION
30 TRIMMING LOWER DIE
30B BASE DIE
30N NEW DIE
31 WORKPIECE RECEIVING PORTION
32 DIE STRUCTURE PORTION
32a RIB
34 ATTACHMENT PORTION
35 LOCATOR
36 U-GROOVE
37 CAM
38 SCRAP CUTTER
39 LIFTING BAR
40 PIERCING LOWER DIE
41 WORKPIECE RECEIVING PORTION
42 DIE STRUCTURE PORTION
43 PROFILE
50 BENDING LOWER DIE
51 WORKPIECE RECEIVING PORTION
52 DIE STRUCTURE PORTION
53 PROFILE
101 DIE
102 PRODUCT SHAPE FORMING PORTION
103 DIE STRUCTURE PORTION
104 GUIDE POST
105 CAM
106 SCRAP CUTTER
107 SPRING
201 DIE
202 PRODUCT SHAPE FORMING PORTION
203 DIE STRUCTURE PORTION
204 GUIDE POST
205 CAM
206 SCRAP CUTTER
207 SPRING
Bo CENTER
No CENTER
O1 CENTER
P1 to P11 FEATURE POINT
α MAGNIFICATION (EXPANSION/CONTRACTION RATIO)

1. A die design system for designing a new die having a magnification different from a magnification of a reference die when the magnification of the reference die is 100%,
the die design system stores reference die data having a plurality of shape data, and the die design system lets a user enlarge or reduce the die data at a desired magnification more than 100% or less than 100% and set new die data to have first shape data among the plurality of shape data, the first shape data being enlarged or reduced at the desired magnification with respect to a predetermined reference point,
the die design system lets the user set the new die data to have second shape data among the plurality of shape data, the second shaped data being moved at a magnification of 100% with respect to the predetermined reference point or the first shape data,
a position of the predetermined reference point is restricted from being moved,
the second shape data is a plurality of second shape data,
the die design system lets the user set at least one of the plurality of second shape data as position adjustment shape data to adjust a position after being moved with respect to the predetermined reference point, and
the position adjustment shape data is set to release a restriction on a movement from the position moved by a movement amount with respect to the predetermined reference point based on the desired magnification, then to move the second shape data to an adjusted position, and then to move the position with respect to the predetermined reference point.

2. The die design system according to claim 1,
the first shape data includes shape data of at least one of a workpiece receiving portion, an insert, and a die structure portion constituting the reference die, and
the second shape data includes shape data of an attachment portion constituting the reference die, and the attachment portion includes at least one of a cam, a scrap cutter, a spring, a U-groove, a lifting bar, a locator, and a piercing punch.

3. (canceled)

4. The die design system according to claim 1,
the reference die data is die data for manufacturing a transfer press die, and
the predetermined reference point corresponds to a center of the transfer press die.

5. The die design system according to claim 1,
the desired magnification is set in a range of more than 100% and less than 120% during the enlargement, and/or is set in a range of 80% or more and less than 100% during the reduction.

6. (canceled)

7. The die design system according to claim 1,
the die design system displays the first shape data and the second shape data, and moves the second shape data by enlarging or reducing the first shape data at the desired magnification.

8. The die design system according to claim 7,
in response to an operation of a mouse, the die design system enlarges or reduces an external dimension frame of the reference die data in real time, and displays the external dimension frame, the first shape data, and the second shape data.

9. The die design system according to claim 1,
the reference die and a neighboring die of the reference die are used together in a transfer press, and a maximum dimension of the reference die, which is a maximum value of the desired magnification, is restricted by a disposition position of the neighboring die.

10. A die design system for designing a new die having a magnification different from a magnification of a reference die when the magnification of the reference die is 100%,
the die design system stores reference die data having a plurality of shape data, and the die design system lets a user enlarge or reduce the die data at a desired magnification α more than 100% or less than 100% and set new die data to have among the plurality of shape data, the first shape data being enlarged or reduced at the desired magnification α with respect to a center reference point of a die structure portion (32),
the die design system lets the user set the new die data to have second shape data among the plurality of shape data, the second shape data being moved at a magnification of 100% where a shape of the second shape data is not changed with respect to the center reference point,
a position of the center reference point is restricted from being moved,
the die design system calculates a movement amount of coordinates of a representative point of the second shape data with respect to the center reference point based on the desired magnification α, and
the die design system displays the first shape data and the second shape data, and moves the second shape data by the movement amount by enlarging or reducing the first shape data at the desired magnification α.
